(19) United States
(12) Patent Application Publication
(10) Pub. No.: US 2009/0087967 A1
(43) Pub. Date: Apr. 2, 2009

(54) PRECURSORS AND PROCESSES FOR LOW TEMPERATURE SELECTIVE EPITAXIAL GROWTH

(76) Inventor: Michael A. Todd, Phoenix, AZ (US)

Correspondence Address: SCHMEISER OLSEN & WATTS, 18 E UNIVERSITY DRIVE, SUITE # 101, MESA, AZ, 85201, US

(21) Appl. No.: 11/559,679

(22) Filed: Nov. 14, 2006

Related U.S. Application Data
(60) Provisional application No. 60/737,040, filed on Nov. 14, 2005.

(51) Int. Cl. H01L 21/20; C09K 13/04; C03C 25/68

(52) U.S. Cl. 438/507; 252/79.1; 216/58; 257/E21.09

(57) ABSTRACT

This invention generally relates to low temperature epitaxy. More specifically, this invention relates to processes for achieving low temperature selective epitaxial growth by chemical vapor deposition of source precursors containing Si or Ge in the presence of bromine or iodine, compositions containing precursors and brominated or iodinated compounds suitable for achieving selective epitaxial growth using the processes, epitaxial layers made using the processes, devices and other types of structures made using the processes, and processes for cleaning epitaxy reactor chambers using a bromine etchant source.

### CROSS REFERENCE TO RELATED APPLICATION

This application claims priority to the earlier provisional application entitled “Low Temperature Selective Epitaxial Growth Precursors and Processes,” Ser. No. 60/737,040, filed Nov. 14, 2005, the disclosures of which are hereby incorporated herein by reference.

### BACKGROUND

1. Technical Field

The invention relates generally to the deposition of semiconductor thin films for integrated circuit fabrication. More particularly, the invention relates to the selective epitaxial growth of thin film materials at low substrate temperatures using chemical vapor deposition reactions.

2. State of the Art

Epitaxy is a specialized thin-film deposition technique used to achieve ordered crystalline growth on a single crystalline substrate. Epitaxy forms a thin film whose material lattice structure and orientation or lattice symmetry is identical to that of the substrate on which it is deposited. Most importantly, if the substrate is a single crystal, then the thin film will also be a single crystal. Representative examples of epitaxial film growth technologies include molecular beam epitaxy, liquid phase epitaxy and vapor phase epitaxy. Epitaxy has many uses, including applications in nanotechnology and in the manufacture of semiconductor and photonic devices, and is the only affordable method of high crystalline quality growth for many semiconductor materials such as silicon (Si), germanium (Ge), silicon-germanium (Si₁Ge), gallium nitride (GaN), gallium arsenide (GaAs) and indium phosphide (InP).

Selective epitaxial growth (SEG) is a process in which films are deposited selectively on a patterned substrate. In particular, SEG processes selectively grow a single-crystalline film on exposed, properly prepared single crystal ‘seed’ windows formed by patterning and etching a dielectric film. The film is grown on the exposed windows without depositing a film on the adjacent, exposed dielectric surfaces. In the selective epitaxial growth (SEG) of silicon, for example, growth occurs only on exposed silicon areas of a silicon substrate. The substrate regions on which silicon growth is not desired are masked by a dielectric film, typically silicon dioxide, silicon nitride, silicon carbon nitride, or silicon oxynitride. Epitaxial Lateral Overgrowth (ELO) is one type of SEG process which can selectively grow a film in the exposed single crystal seed windows until the thickness of the film approaches or exceeds that of the masking dielectric film. If growth occurs after that point in the process, the epitaxial film begins to grow over the masking dielectric layer and selectivity is significantly reduced or lost.

The use of the SEG process permits the fabrication of novel structures such as silicon devices and integrated-circuit structures. SEG processes are ‘self-aligned’ in that they do not require additional masking steps to achieve the final desired film or structure. Therefore, due to the elimination of mask misalignments, they provide the means to manufacture structures such as semiconductor devices and integrated circuits at substantially reduced cost and potentially much higher yield, particularly for small-featured devices. As a result, SEG processes have been demonstrated to have great utility in the fabrication of many important structures, particularly semiconductor structures such as raised/elevated source-drain (RSD or ESD) structures, vertical MOSFET devices, retrograde N-well and P-well CMOS devices, dynamic random access memory (DRAM) structures, self-aligned SiGe and SiGeC type alloy thin film heterojunction bipolar transistors (HBT), BiCMOS devices, engineered substrates such as Silicon on Insulator (SOI), and integrated circuits (e.g. fast-cache memory chips) used in communication networks such as fixed or mobile Ethernet, microwave, millimeter-wave, wireless, and optical fiber networks.

Low-temperature epitaxial growth provides several additional advantages with respect to device fabrication, including improved electrical performance of advanced complementary metal oxide semiconductor (CMOS) and BiCMOS technologies. In general, low thermal budget SEG processes are highly desirable during fabrication because they avoid solid-state diffusion within pre-existing structures. Additionally, low temperature processes are believed to reduce thermal stress and improve the crystalline quality of the ‘sidewall’ and ELO thin film materials. Furthermore, low temperature processes are conducted in a strongly kinetically-controlled reaction regime, thereby helping to minimize the active area size dependence of detrimental chemical loading effects.

In order to achieve selectivity, contemporary SEG processes typically involve either the use of chlorinated source precursors or etchants, or the use of ultra-high vacuum (UHV) conditions and very low precursor partial pressures. However, due to kinetic limitations associated with byproduct desorption during SEG, the use of chlorine in any form requires temperatures in excess of 700° C. to selectively grow films using materials that do not contain germanium. In addition, the growth rate of silicon-based films is typically very slow at temperatures less than about 750° C. As a result, when using chlorinated precursors or etchants, only SEG films containing germanium are commercially practical at temperatures less than about 750° C. Therefore, although the process can sometimes be carried out at reduced total pressures (e.g. UHV conditions), the use of chlorine to achieve selective epitaxial growth (SEG) of silicon effectively limits the practical processing temperature to greater than about 735° C., with temperatures greater than about 825° C. being more commonly employed in order to enable reasonable film growth rates. In addition, for films grown at temperatures below about 750°, it is usually very difficult to remove residual chlorine from the films after epitaxy.

The use of UHV conditions for SEG processes (UHV-SEG) is also undesirable due to system cost, complexity and maintenance in a semiconductor manufacturing environment. Additionally, UHV-SEG process conditions generally require the use of stainless steel and other metal components that are incompatible with halogenated precursors or etchants. As a result, in situ chamber etching is not generally used to remove films that deposit within the chamber during UHV-SEG, resulting in dopant ‘memory’ effects that can adversely affect film properties. In addition, due to the lack of suitable UHV etchants, UHV SEG processes must generally rely on ‘natural’ selectivity between single crystal seed windows and the exposed dielectric surfaces. However, ‘natural’ selectivity is poor, particularly for silicon nitride-based dielectrics, resulting in very narrow or non-existent process windows that are generally unsuitable for semiconductor manufacturing.

Chemical vapor deposition (CVD) is a chemical process for depositing thin films containing various chemical elements onto substrates and other types of fabricated surfaces. In a typical CVD process, the substrate is exposed to one or more volatile precursors which react or decompose on the substrate surface to produce the desired deposit. Frequently, volatile byproducts are also produced, which are removed by gas flow through the reactor chamber. Chemical vapor deposition SEG (CVD-SEG) of Si-containing and other Group IV materials and alloys has been demonstrated using a wide range of precursor chemistries and processes (e.g. pressure, flows, cycles, etc.). For Si-containing films, which make up most of the market to date, these processes rely on at least one of three approaches for achieving selective epitaxial growth: (a) the use of chlorinated sources or chlorinated etchants at high temperature (i.e. greater than about 750° C.); (b) the use of chlorinated and non-chlorinated sources at very high temperature (i.e. greater than about 900° C.); and (c) the use of ultra-high vacuum (UHV) processing conditions.

As opposed to the high temperature, near thermodynamic equilibrium condition processes described above, low temperature CVD processes operate in a temperature regime that is far from equilibrium with regard to the chemical reactions that are taking place. These non-equilibrium processes are generally described as surface reaction rate limited or kinetically limited. Low temperature film deposition/growth rates are generally controlled by the dissociative adsorption of precursor molecules, which requires the availability of reactive sites (i.e. exposed ‘dangling bonds’ or reactive defect sites) on the surface of the evolving film. At low temperature, the availability of reactive sites is limited by the desorption of the byproducts produced through the decomposition of the precursor molecules. Therefore, the film growth rate of a given process is controlled by the chemical reactions of the precursors with the exposed surfaces of the substrate for a given set of temperature, total pressure and partial pressure conditions. In general, in order to achieve a high film deposition rate at low temperature, it is desirable to use precursors that have a high probability of dissociative adsorption with available reaction sites (a high reactive sticking coefficient, SR), coupled with a high surface mobility in the adsorbed state and the production of reaction byproducts that rapidly desorb from the surface of the evolving film to generate additional sites for dissociative adsorption at the temperature of interest.

For SEG processes, it is desirable to grow single crystal films on properly prepared single crystal seed windows which are exposed within a dielectric film that has been patterned and etched, while avoiding deposition on the exposed dielectric surfaces that are co-planar with the seed window surfaces, and to carry out these film deposition processes in commercially available reactor chambers. Therefore, the chemical reactions of the precursors for a given set of temperature, total pressure and partial pressure conditions must be considered for both the single crystal seed windows and the exposed areas of the dielectric. Contemporary SEG processes rely primarily upon the use of two mechanisms to achieve selectivity between the single crystal seed windows and the exposed dielectric surfaces; ‘natural’ selectivity, or the use of an etchant which is used to etch non-single crystal film nuclei from exposed dielectric surfaces during the CVD process.

Processes that exploit ‘natural’ selectivity rely on the difference between the reactivity of the single crystal seed window surface relative to that of the dielectric surface. The difference in reaction rates is evidenced through an ‘incubation’ period during which growth in the single crystal seed windows is taking place, but deposition on the dielectric surface is not taking place. After the incubation period is exceeded, a film nucleates and begins to form a continuous layer over the dielectric, thus losing selectivity. Natural selectivity can be best exploited using low precursor partial pressures and the highest vacuum level (or the lowest total pressure) possible. Although processes that exhibit selectivity based upon ‘natural’ selectivity can be developed, they are limited in utility from a number of perspectives. For fabrication of films containing Si, for example, such processes are limited by the total Si-containing film thickness that can be grown in the seed windows before nucleation takes place on the dielectric, and often have very narrow process windows that are not ideally suited for semiconductor manufacturing. Furthermore, the natural selectivity mechanism is a strong function of the identity of the masking dielectric. The natural selectivity that can be achieved for SiO₂, for example is much greater than that which can be achieved for silicon nitride dielectrics, and thus SiO₂ is the most desirable dielectric in most SEG applications. Unfortunately, most contemporary applications require the use of silicon nitride-based dielectrics. This results in extremely narrow and undesirable process windows for SEG. Additionally, ‘natural’ selectivity is also affected by the chemical nature of the Si-containing film that is being grown. The addition of common and often necessary dopant elements to the process can severely degrade natural selectivity, resulting in even more narrow or, in the extreme case, non-existent SEG process windows. In general, ‘natural’ selectivity is maximized for processes that employ high substrate temperature (for SiO₂ dielectrics) or very low total pressure and very low precursor partial pressures, limiting its utility in processes conducted in the majority of contemporary CVD reactors used in semiconductor manufacturing.

By far more common are SEG processes that utilize an etchant to remove non-single crystal film nuclei from the exposed dielectric surfaces through the formation of volatile products generated through the reaction of the etchant and the nuclei formed on the dielectric. The etchant may be introduced as a formal reactant gas/vapor, or may be generated in situ through the decomposition of the precursor molecules themselves. Almost universally, the etchant employed in contemporary SEG processes is chlorine, typically supplied in the form of Cl₂, HCl or SiCl₂, although some research into the use of atomic hydrogen as an etchant has also been conducted. However, as discussed earlier, the use of chlorine as an etchant is severely limiting in terms of allowable process temperatures because, due to kinetic limitations, the growth rate of single crystalline films and the etch rate of nuclei is exceedingly slow for temperatures less than about 750° for films that do not contain germanium as a substituent. Therefore, the temperature limitations for SEG of Si-containing materials arise primarily from the use of chlorine. Furthermore, the use of atomic hydrogen as a nuclei etchant is impractical for temperatures greater than about 300° C. due to exceedingly low etch rates, thus making it unsuitable for most semiconductor manufacturing processes. Such restrictions limit the potential of the SEG technique to provide thin film materials which have the properties required for contemporary microelectronics.

Information relevant to attempts to address one or more of these problems can be found in the following references: U.S. Pat. No. 3,653,991; U.S. Pat. No. 4,891,201; U.S. Pat. No. 5,037,775; U.S. Pat. No. 5,937,299; U.S. Pat. No. 6,017,795; U.S. Pat. No. 6,197,645; U.S. Pat. No. 7,112,495; U.S. Patent Application No. 2004/0224089; and P. Ribot & D. Dutartre, P., “Low-Temperature Selective Epitaxy of Silicon with Chlorinated Chemistry,” Materials Science and Engineering: B, (14 Feb. 2002) Volume 89, Number 1, pp. 306-309(4). However, each one of these references suffers from one or more of the following disadvantages:

1. the starting materials had high temperature sensitivity, or were not pure;

2. the precursor source composition was not fixed as a function of the temperatures investigated;

3. SEG was conducted at temperatures well above the surface reaction rate limited regime;

4. complex chemical loading effects were apparent;

5. the choice of carrier gas resulted in undesirable disproportionation reactions;

6. the process parameters disclosed were insufficient or inappropriate for fabricating viable films using some or all of the starting materials described;

7. the films were amorphous, non-selectively deposited on dielectric substrates, or contained measurable amounts of halogen;

8. the use of chlorinated etchants produced a residue that was difficult to remove from the reactor chamber or adversely affected equipment lifetime; or

9. the precursor materials disclosed were ineffective in the absence of an extrinsic etchant.

Thus there remains a need within the semiconductor industry for precursors and processes that are capable of providing SEG of Si-containing and Ge-containing materials at temperatures below about 750° C. that do not require the use of ultra-high vacuum conditions.

### DISCLOSURE OF THE INVENTION

The present invention relates to processes for low thermal budget SEG of thin film materials in single crystal seed windows patterned in dielectric layers formed on substrates, compositions for achieving selective epitaxial growth using the processes; layers fabricated using such processes, structures containing such layers, and processes for cleaning surfaces inside a reactor chamber. In particular, low temperature SEG processes for growing Si-containing and Ge-containing layers, using mixtures of chemical source precursors and compounds containing bromine (Br) or iodine (I), can be used to enable selective epitaxial growth of thin film materials containing Si or Ge at temperatures below about 750° C. Furthermore, the processes of the invention proceed with high growth rates in reactor systems that do not use UHV conditions.

The low temperature SEG process of the invention can be achieved using CVD, with growth rates commensurate with manufacturing semiconductor integrated circuits and engineered semiconductor substrates. Therefore, the present invention enables practical and cost-effective SEG of Si-containing and Ge-containing materials over a broad range of temperatures, total pressures and partial pressures, providing solutions to long standing needs within the semiconductor manufacturing industry.

In a first aspect, the present invention generally provides a low temperature process for selective growth of an epitaxial layer on a patterned substrate, a process in which a patterned substrate is introduced into a deposition chamber, the substrate temperature and pressure of the chamber is optimized for growth of the layer, one or more source precursors and one or more compounds containing elemental bromine or iodine are introduced into the chamber, and the substrate temperature is maintained at less than about 750° C. for a period of time sufficient to selectively grow an epitaxial layer on the substrate. In one embodiment, the temperature of the substrate during deposition is from about 400° C. to about 750° C., or any temperature range therein. In a further embodiment, the total pressure is less than about 800 Torr.

In another embodiment, chemical vapor deposition is used to selectively grow the epitaxial layer. In yet another embodiment, the compound containing bromine or iodine is pre-heated prior to introducing the compound into the chamber. In a further embodiment, one or more compounds containing bromine or iodine are mixed with a carrier gas prior to introducing them into the chamber.

In another embodiment one or more of the source precursors contains Si, Ge, C, Sn, or combinations thereof. In yet another embodiment, the source precursors can be one or more silanes, halosilanes, halodisilanes, halotrisilanes, halomethanes, silylmethanes, halosilylmethanes, halosilylhalomethanes, or combinations thereof. In a further embodiment, the source precursor can be one or more germanes, halogermanes, halodigermanes, halomethanes, germylmethanes, halogermylmethanes, halogermylhalomethanes, or combinations thereof.

In another embodiment, the compound containing bromine is a bromine etchant source. In yet another embodiment, the compound containing bromine is a source precursor.

In another embodiment, two or more compounds containing bromine are introduced into the chamber. In yet another embodiment having two or more compounds containing bromine, at least one of the compounds is a bromine etchant source and at least one of the compounds is a source precursor.

In another embodiment, two or more source precursors are introduced into the chamber. In yet another embodiment having two or more source precursors, at least one of the precursors contains bromine. In a further embodiment having two or more source precursors, at least one precursor is a Br etchant source. In a yet further embodiment having two or more source precursors, at least one precursor contains Ge and at least one precursor contains Si.

In another embodiment, at least one precursor contains Si and the substrate temperature is less than about 750° C. In yet another embodiment, at least one precursor contains Ge and the substrate temperature is less than about 700° C. In a further embodiment, at least one precursor contains Sn and the substrate temperature is less than about 650° C.

In another embodiment, two or more source precursors are introduced into the chamber and at least one of the precursors contains Sn, at least one of the precursors contains Ge, and the substrate temperature is less than about 500° C.

In another embodiment, one or more compounds containing bromine and one or more source precursors is selected from the group consisting of: Br₄₋ₓSiHₓ (x=0-3); (BrₓH₃₋ₓSi)₂ (x=1-2); Br₄₋ₓGeHₓ (x=0-3); (BrₓH₃₋ₓGe)₂ (x=1-2); I₄₋ₓSiHₓ (x=0-3); (IₓH₃₋ₓSi)₂ (x=1-2); I₄₋ₓGeHₓ (x=0-3); (IₓH₃₋ₓGe)₂ (x=1-2); and SnD₄.

In a second aspect of the invention, a selectively grown epitaxial layer fabricated according to the invention is provided. In one embodiment, the epitaxial layer contains Si, Ge, Sn, C, Br, I, or combinations thereof.

In a third aspect of the invention, a device or other type of structure containing a selectively grown epitaxial layer fabricated according to the invention is provided. In one embodiment, the structure is a MOSFET device, an emitter structure, an elevated source-drain structure, a heterojunction bipolar transistor structure, an epitaxial lateral overgrowth structure, a DRAM structure, an engineered substrate structure, or a component thereof.

In a fourth aspect of the invention, a process for cleaning residue from one or more surfaces inside a deposition chamber is provided, a process in which at least one etchant source containing bromine is introduced into the chamber, a substrate temperature and a total pressure is provided within the chamber, and the source is flowed for a period of time sufficient to remove a substantial portion of the residue. In one embodiment, the etchant source containing bromine is pre-heated prior to introducing the source into the chamber. In another embodiment, the etchant source is HBr, Br₂ or a combination thereof. In another embodiment, the substrate temperature is greater than about 550° C. In yet another embodiment, the total pressure is less than about 800 Torr. In a further embodiment, the etchant source is mixed with a carrier gas prior to introducing the etchant source into the chamber.

In a fifth aspect of the invention, a surface cleaned according to the invention is provided. In one embodiment, the surface is a patterned substrate, an inner surface of the chamber, a chamber component, an object having no physical or functional connection with the chamber, or combination thereof.

In a sixth aspect of the invention, a composition for selective epitaxial growth is provided, the composition containing one or more source precursors and at least one compound containing elemental bromine or iodine. In one embodiment, one or more source precursors in the composition contain Si, Ge, C, Sn or combinations thereof. In another embodiment, one or more source precursors in the composition can be silanes, halosilanes, halodisilanes, halotrisilanes, halomethanes, silylmethanes, halosilylmethanes, halosilylhalomethanes, or combinations thereof. In yet another embodiment, one or more source precursors in the composition are germanes, halogermanes, halodigermanes, halomethanes, germylmethanes, halogermylmethanes, halogermylhalomethanes and combinations thereof. In a further embodiment, the compound containing bromine is a bromine etchant source. In a yet further embodiment, the compound containing bromine is a source precursor.

In another embodiment, the composition includes two or more compounds containing bromine. In yet another embodiment having two or more compounds containing bromine, at least one of the compounds is a bromine etchant source and at least one of the compounds is a source precursor.

In another embodiment, a composition for selective epitaxial growth containing at least two source precursors and at least one compound containing elemental bromine or iodine is provided. In yet another embodiment, at least one of the two precursors contains bromine. In a further embodiment, at least one of two precursors is a Br etchant source. In yet a further embodiment, at least one of the two precursors contains Ge and at least one of the two precursors contains Si.

The above-mentioned as well as other features and advantages of the present invention will be apparent from the following more detailed description of the particular embodiments of the invention, as illustrated in the accompanying drawings.

The foregoing general description and the following detailed description are exemplary and explanatory only and are not restrictive of the invention, as defined in the appended claims.

### DETAILED DESCRIPTION OF EMBODIMENTS OF THE INVENTION

The present invention provides processes that can enable high throughput SEG processes for materials such as intrinsic silicon (Si) and germanium (Ge), SiC and GeC alloys, SiGe alloys, SiGeC alloys and doped silicon, germanium, SiC and GeC alloys, SiGe alloys, and SiGeC alloys at temperature less than about 750° C. in the types of commercially available CVD reactors commonly employed in semiconductor manufacturing.

Generic chemical formulae are commonly used herein for discussing groups of compounds containing the same chemical elements, regardless of stoichiometry (i.e. where no stoichiometry is implied), including without limitation “SiGe”, “SiC”, “SiGeC”, “Ge”, “5 nC”, “GeC”, “SnGe”, and “SiGeSn.” SiGe, for example, is a group of compounds containing Si and Ge that includes without limitation the following alloys: Si₁₋ₓGeₓ where 0<x<1.

The following description presents embodiments of the invention representing various modes contemplated for practicing the invention. This description is not to be taken in a limiting sense but is made merely for the purpose of describing the general principles of the invention, whose scope is defined by the appended claims.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of the “a” or “an” are employed to describe elements and components of the invention. This is done merely for convenience and to give a general sense of the invention. This description should be read to include one or at least one and the singular also includes the plural unless it is obvious that it is meant otherwise.

Unless otherwise defined, all technical and scientific terms used herein have the same meaning as commonly understood by one of ordinary skill in the art to which this invention belongs. Although processes and materials similar or equivalent to those described herein can be used in the practice or testing of the present invention, suitable processes and materials are described below. All publications, patent applications, patents, and other references mentioned herein are incorporated by reference in their entirety. In case of conflict, the present specification, including definitions, will control. In addition, the materials, processes, and examples are illustrative only and not intended to be limiting.

The following definitions refer to the particular embodiments described herein and are not to be taken as limiting; the invention includes equivalents for other undescribed embodiments.

As used herein, the term “active area” is intended to mean an exposed surface on a substrate bordered by a patterned dielectric layer; equivalent terms—seed window. Such exposed surfaces are active growth areas during SEG processes.

As used herein, the term “deposition chamber” is intended to mean any type of chamber which can be used to deposit semiconductor material, including without limitation ASM Epsilon single wafer reactor systems, Centura single wafer reactor systems, and various horizontal or vertical batch wafer furnace systems; equivalent terms—reactor chamber.

As used herein, the term “dielectric” is intended to mean an insulating layer or surface which is located on the same side of a substrate as the single crystal seed windows, and which is exposed during SEG of epitaxial materials on the seed windows; equivalent terms—masking dielectric.

As used herein, the term “epitaxial layer” or “epi layer” is intended to mean a single crystal layer formed on top of a single crystal substrate. An epitaxial layer may have a different doping level or doping type than the substrate upon which the epitaxial layer is formed. In some cases, the epitaxial layer may be a completely different type of material than the substrate upon which it is grown.

As used herein, the term “etchant” or “etchant source” is intended to mean a material containing one or more chemicals capable of removing nuclei from an exposed dielectric surface.

As used herein, the term ‘masking dielectric’ is intended to mean an insulating layer or surface which is located on the same side of a substrate as the single crystal seed windows, and which is exposed during SEG of epitaxial materials on the seed windows; equivalent terms—dielectric.

As used herein, the term “precursor” or “source precursor” is intended to mean a precursor material capable of providing a source of Si, Ge, C, Sn, or combination thereof for fabricating an epitaxial film.

As used herein, the term ‘patterned substrate’ is in intended to mean a substrate having one ore more patterned dielectric layers which border single crystalline seed windows.

As used herein, the term “seed window” is intended to mean an exposed surface on a substrate bordered by a patterned dielectric layer; equivalent terms—active area. The seed windows are active growth areas during SEG processes.

As used herein, the term ‘selective epitaxial growth’ or “SEG” is intended to mean growth or deposition of an epitaxial film preferentially within single crystal seed windows on a patterned substrate, while avoiding spurious nucleation and film growth on the other exposed dielectric surfaces, until the point at which the SEG film thickness approaches or exceeds that of the masking dielectric film.

As used herein, the term “structure” when referring to a structure containing a film deposited by SEG is intended to mean a device, device component, or other fabricated structure containing the film, including without limitation a MOSFET, emitter structure, elevated source-drain structure, HBT structure, epitaxial lateral overgrowth structure, DRAM structure, and engineered substrate structure.

As used herein, the term “substantial portion” when referring to removal of residue from within a chamber is intended to mean that all or most of any undesirable film deposits within the chamber, including without limitation those on the inner surfaces of the chamber or other chamber components, are removed.

As used herein, the term “total pressure” when referring to the pressure within a deposition chamber is intended to mean the total pressure of the mixture of gases within the chamber at equilibrium; equivalents—sum of the partial pressures of the gases present in the chamber.

As used herein, the term “substrate temperature” or “temperature” when referring to the temperature of a substrate within a deposition chamber is intended to mean the temperature of the substrate or substrates as measured by a thermocouple or other suitable means.

The present invention generally relates to processes for low thermal budget SEG of chemical materials in single crystal seed windows patterned in dielectric layers formed on substrates. More specifically, the embodiments of the present invention include low temperature processes for selective deposition of an epitaxial layer on a patterned substrate, compositions suitable for achieving selective epitaxial growth using the processes, epitaxial layers made using such processes, structures containing such layers, and processes for cleaning surfaces inside a reactor chamber.

Preferably, the growth of the Si-containing or Ge-containing material takes place only on the surfaces of the seed windows and along the dielectric ‘sidewalls’ bordering them, until the point when the thickness of the SEG film approaches or exceeds that of the masking dielectric film thickness. The number of non-single crystal film nuclei present on the exposed dielectric surfaces at the conclusion of the SEG of the Si-containing or Ge-containing materials is preferably from less than about 1×10⁶ to less than about 1 nuclei per square centimeter of exposed dielectric surface area. The number of nuclei can be measured using a number of known techniques, including without limitation optical microscopy, electron microscopy, or optical surface scanning techniques based upon scattered light.

For processes in which the thickness of the Si-containing or Ge-containing SEG film exceeds that of the masking dielectric, selective epitaxial growth from the seed windows will begin to cover the exposed dielectric surfaces through a process known as Epitaxial Lateral Overgrowth (ELO). In this case, the films selectively growing from the seed windows over the dielectric surfaces will at some point coalesce, resulting in an epitaxial film that completely covers the masking dielectric layer. Such ELO processes are also an embodiment of the present invention, particularly with respect to the formation of engineered substrates in which the ELO film is further used in device fabrication.

Three distinct types of SEG processes can generally be provided by the present invention: (a) those that formally include a Br-etchant source as an independently introduced reactant; (b) those that include a Br-etchant source that can be generated in situ through the decomposition of one or more brominated precursors in addition to a formally introduced Br-etchant source; and (c) those that include only a Br-etchant source generated in situ through the decomposition of one or more source precursors. This type of etching can be effective at temperatures greater than about 500° C. for Si-containing materials and greater than about 400° C. for Ge-containing materials, and becomes more effective as the total pressure is reduced. The products of the etching reactions preferentially include SiBrₓ and GeBrₓ (where x=1-4), as opposed to chlorine which yields only SiCl₂ as an etch product at temperature below about 900° C. The additional product channels available for Br-based etching, relative to Cl-based etching, may also promote more effective etching of nuclei at low temperature. In particular, the evolution of SiBr (g) and GeBr (g) as etch products may provide enhanced etch rates at low substrate temperature relative to Cl-based etching. Therefore, the use of Br-based etchants can result in more efficient etch processes that require less added Br (relative to Cl-based etchants) in order to maintain selectivity to the exposed masking dielectric layers. Most importantly, the use of Br-based etchants enables significantly lower substrate temperatures for SEG of Si-containing and Ge-containing films than are possible for Cl-based etchants, while affording growth rates that are commercially attractive for semiconductor manufacturing.

In one embodiment, a Br-etchant source can be formally introduced into the SEG process. In another embodiment, the Br can be supplied through the decomposition of one or more of the sources used to selectively grow the Si-containing or Ge-containing film. That is, a Br-etchant source may not be formally introduced as a reactant gas/vapor; the Br is supplied in situ via the decomposition of the source precursors. In yet another embodiment, a Br-etchant source can be formally introduced into the SEG process, and supplementary Br can be generated in situ through decomposition of one or more of the source precursors. That is, a Br-etch source can be formally introduced as a reactant gas/vapor and additional Br is supplied in situ via the decomposition of the source precursors. The sources of Br and their use in processes to selectively grow Si-containing and Ge-containing films will be detailed later and illustrated through examples. Thermal decomposition of the Br sources is the preferred method of activation, but other methods are also suitable, including without limitation plasma activation, remote plasma activation and photo excitation.

The low temperature processes of the present invention involve the use of at least one source precursor and at least one composition comprising bromine. Preferably, at least two source precursors are used. In one embodiment, one or more source precursors can be combined with a Br-etchant to selectively grow a Si-containing or a Ge-containing film on single crystal seed windows exposed within a patterned dielectric layer. The source of bromine may include without limitation elemental bromine (Br₂), a mixture of Br₂ and a carrier gas, pure hydrogen bromide (HBr) gas, or a mixture of HBr and a carrier gas. Additional sources capable of supplying Br through activation or decomposition may also be used, provided that they do not adversely affect the quality or properties of the SEG films. In certain embodiments, the Br source may be heated prior to introduction into the reactor chamber containing the patterned substrates. A Br-etchant source can be heated to a temperature approximately 50° C. or more below its thermal ‘cracking’ temperature, more preferably to about 100° C. or more below its thermal ‘cracking’ temperature, where the thermal ‘cracking’ temperature is considered to be the temperature at which the Br source decomposes at least partially into its elemental constituents.

The flow rate of the Br-etchant source can be preferentially adjusted in combination with the flow rates of the other sources and the carrier gas flow rate for any given substrate temperature and total pressure. Optimization of the Br-etchant source flow rate and partial pressure relative to the other sources and the carrier gas can be achieved through routine experimentation that varies the flow rates and partial pressures of the precursors. In general, those combinations of flow rates and resulting partial pressures that yield a growth rate equal to that on a bare (unpatterned) single crystal substrate in the absence of the Br-etch source are preferred for the dielectric patterned substrate when the Br source is included in the film growth process (for otherwise fixed temperature and total pressure conditions and a given patterned substrate), with the constraint that the SEG films are grown at or near the maximum possible growth rate while maintaining acceptable crystal quality, within-wafer thickness and elemental concentration uniformity, and while maintaining acceptable selectivity to the dielectric.

Br-based etchants can also be used for the thermal etching of Si-containing and Ge-containing materials at high etch rates and at temperatures lower than those required when using Cl-based etchants. Therefore, they can be very useful for reactor chamber cleaning and in situ wafer etching applications. In one embodiment of the present invention, a Br-based etchant may be used for cleaning surfaces within a reactor chamber, including without limitation a patterned substrate, an inner surface of the chamber, a chamber component, an object having no physical or functional connection with the chamber, and combinations thereof. The surface cleaning process is preferably carried out at a substrate temperature greater than about 550° C. and a total pressure of less than about 800 Torr. The process may use the same types of etchants described above for selective epitaxial growth, preferably HBr, Br₂ and mixtures thereof. In one embodiment, the etchant may be pre-heated prior to introduction into the reactor chamber. In another embodiment, the etchant source may contain a carrier gas.

The growth of selective epitaxial films of germanium and Ge-containing films on various substrates can also be provided by this invention. Similar to the cases for selective epitaxial growth of Si-containing films, Ge-containing films can be selectively grown using Ge-source precursors either through reactions in which a Br-etchant source may be formally introduced as a gas or vapor reactant or through processes in which the Br-etchant source can be generated in situ through the decomposition of one or more brominated source precursors. In general, germanes are more reactive than silanes at lower substrate temperatures, and the desorption of byproducts from the Ge-containing film surface occurs more rapidly at a given temperature than the corresponding desorption from a film surface that does not contain Ge. As a result, selective epitaxial film growth of Ge-containing films can take place at lower substrate temperature relative to films that do not contain germanium, and can also use chlorinated etchant sources for etching reactions and film growth. However, the use of a Br-etchant source enables selective epitaxial growth of Ge-containing films at lower temperature relative to the use of Cl-etchants and may also enable higher growth rate processes by virtue of more rapid byproduct desorption at a given substrate temperature, partial pressures and total pressure.

Although the use of Br-etchants as described in these embodiments is preferred, the use of I-etchants can also be suitable for the present invention.

The processes of the present invention are intended to provide selective epitaxial growth of Si-containing and Ge-containing materials on properly prepared, patterned substrates through the use of low temperature, chemical vapor deposition (CVD) techniques, including without limitation plasma enhanced (PE-CVD), remote plasma enhanced (remote PE-CVD), photo-CVD, low pressure (LP-CVD), ultra-high vacuum (UHV-CVD), reduced pressure (RP-CVD), rapid thermal (RT-CVD), atmospheric pressure CVD, ‘remote thermal’ CVD, ‘conventional’ thermal CVD, and combinations thereof. Various types of deposition chambers are suitable for the invention, including without limitation reactor chambers such as ASM Epsilon single wafer reactor systems, Centura single wafer reactor systems (Applied Materials, Santa Clara, Calif.), and various horizontal and vertical batch wafer furnace systems (ASM International, Bilthoven, The Netherlands; Tokyo Electron Corporation (TEL), Yokohama City, Japan; and Applied Materials, Santa Clara, Calif.).

A multitude of substrate types can be used with the invention, including without limitation single crystal silicon, doped single crystal silicon, SiGe, SiC, SiGeC, Ge, 5 nC, GeC, SnGe, SiGeSn (either strained, partially strain-relaxed or fully strained relaxed), Silicon On Insulator (SOI), Silicon On Sapphire (SOS), strained silicon, strained silicon on insulator, and III-V compound semiconductors such as GaAs, and InP. Patterned substrates can be of any desirable size, shape and thickness, but circular wafers having a diameter of 2 inches or greater are generally used in the semiconductor industry, as are square or rectangular substrates such as those used in flat panel displays. Typical processes for properly preparing the single crystal seed windows for SEG include without limitation hydrogen fluoride (HF) and pre-bake treatments. HF treatments substantially remove native oxide from the surfaces of the single crystal seed windows, and a ‘pre-bake’ or other in-situ cleaning step removes any small amounts of residual contamination that may remain on single crystal growth surfaces after the HF-acid etch that may otherwise result in defective films.

Seed windows for the present invention can have various sizes, shapes, densities and spacing, and are typically oriented along preferential crystallographic planes as closely as possible in order to minimize faceting of the SEG films. The most desirable pattern is usually dependent upon the application in question and can be optimized for a given application using conventional means.

A broad range of masking dielectric materials are suitable for the present invention, including without limitation silicon oxides (SiO), silicon nitrides (SiN), silicon oxynitrides (SiON), silicon carbides (SiC), silicon oxygen carbides (SiOC) and silicon carbon nitrides (SiCN), all of which may contain small concentrations of additional elements including hydrogen. Additional dielectric materials suitable for the invention include without limitation metal oxides, metal nitrides, metal oxynitrides, metal silicates and metal silicates doped with nitrogen which, for example, are being explored for use as gate dielectric materials and contacts, and include those metals from Groups 2, 3, 4, 5, 6, 7, 8, 9, 10, 11, 12 and 13 as defined in the chemical periodic table. Further suitable dielectric materials include without limitation germanium oxides, germanium nitrides, germanium oxynitrides and various III-V compound semiconductor layers that may, for example, be used to passivate III-V-based semiconductor devices.

A number of carrier gases are suitable for use with the invention, including without limitation H₂, Ar, He, Ne, N₂, and mixtures thereof. Preferably, the carrier gas is H₂. Methods for delivering precursors to the reactor chamber housing the substrate (deposition chamber) are generally dependent upon the chemical properties of the precursors being used, including without limitation metering devices for gases, bubbling systems for liquids, and vaporizers for solids. Suitable substrate supports within the reactor chamber include without limitation single wafer reactor platforms and batch wafer reactor platforms (vertical or horizontal platforms).

Therefore, many low temperature SEG processes are possible when extrinsic or in situ Br-based or I-based etchants are utilized according to the present invention, opening up a broad range of potential precursors for the SEG of the Si-containing or Ge-containing films. Exemplary materials and SEG processes are discussed below as a function of the stoichiometry of the Si-containing or Ge-containing films to be selectively grown.

Case 1: Intrinsic Silicon+Extrinsic Br-Etch Source Reactant

When the Si-containing film to be selectively grown is intrinsic silicon, the following classes of silicon source precursors are preferred for use with an independently introduced Br-etch source reactant:

(1) silanes of the general formula SiₙR₂ₙ₊₂ where n=1-4 and R=H, D or mixtures thereof;

(2) halosilanes of the general formula SiR₄₋ₙXₙ where n=0-4, R H, D or combinations thereof, and X=Br, I or combinations thereof;

(3) halodisilanes of the general formula X_{y}RₘSi—SiRₙX_{z} where n m=0, 1 or 2 independent of one another, y=z=1-3 independent of one another, y+m=3, n+z 3, R=H, D or combinations thereof, and X=Br, I or combinations thereof; and

(4) halotrisilanes of the general formula X_{y}RₘSi—SiR₂—SiRₙX_{z} where n=m=0, 1 or 2 independent of one another, y=z=1, 2 or 3 independent of one another, y+m=3, n+z=3, R=H, D or combinations thereof, X=Br, I or combinations thereof.

Combinations of the foregoing classes of chemical precursors described in Classes (1)-(4) can also be used. In this embodiment, the use of iodine-containing precursors is preferred.

Case 2: Intrinsic Silicon+In Situ Br-Etchant

When the Si-containing film to be selectively grown is intrinsic silicon and the process does not include a formally introduced Br-etchant source, the Br used to etch the nuclei from the exposed dielectric surfaces is supplied in situ from the decomposition of the sources used to grow the Si-containing film. Preferably, halosilane precursors (2) as described above in Case 1, where X=Br and n=1 or 2, or halodisalane precursors (3) as described above in Case 1, where X=Br and y=z=1 or 2, are preferred.

Mixtures of compounds described in Classes (1)-(3) above are also useful for the invention, In this embodiment, the use of bromine-containing precursors is preferred.

Case 3: Boron-Doped Silicon

When the film that is to be selectively grown is boron-doped silicon, sources for the boron component of the film are added to the film growth reaction. The preferred precursors for the silicon component of the film are those described previously in Cases 1 and 2, depending upon whether or not a Br-etchant is formally introduced as a reactant. Any source of B that yields selectively grown, boron-doped silicon films can be utilized without departing from the scope of the invention, including without limitation B₂H₆, BBr₃ and BI₃. In general, the amount of boron precursor introduced is small relative to the silicon source precursor, so the use of BCl₃ is not prohibitive in terms of surface kinetics for temperature in excess of about 650° C., but it is less preferred. The amount of boron precursor used will depend upon the total dopant level desired within the selectively grown boron-doped Si-containing film. Typical boron doping levels are between approximately 1 e¹⁵ atoms/cm³ and 1 e²¹ atoms/cm³.

Case 4: N-Type-Doped Silicon

When the film that is to be selectively grown is N-type doped silicon (e.g. silicon doped with one of phosphorus, arsenic or antimony), sources for the N-type component of the film are added to the film growth reaction. The preferred precursors for the silicon component of the film are those described previously in Cases 1 and 2, depending on whether or not a Br-etchant source is formally introduced as a reactant. Any source of N-type dopant that yields selectively grown, N-type-doped silicon films can be utilized without departing from the scope of the invention, including without limitation PH₃, PBr₃, PCl₃, AsH₃, AsBr₃ and AsCl₃, SbH₃ and SbD₃. In general, the amount of N-type dopant precursor that is introduced is small relative to the silicon source precursor, so the use of chlorides is not prohibitive in terms of surface kinetics for temperature in excess of about 650° C., but it is less preferred. The amount of N-type dopant precursor used will depend upon the total dopant level desired within the selectively grown N-type-doped silicon film. Typical doping levels are between approximately 1 e¹⁵ atoms/cm³ and 1 e²¹ atoms/cm³.

Case 5: Si_{1-y}C_{y} Alloy Films

When the film that is to be selectively grown is a Si_{1-y}C_{y} alloy film, sources for the carbon component of the film are added to the film growth reaction. The preferred precursors for the silicon component of the film are those described previously in Cases 1 and 2, depending upon whether or not a Br-etchant is formally introduced as a reactant. In some cases, the carbon source may also be a source of additional silicon, as well as the source of carbon. The preferred carbon source precursors considered in this invention include:

(5) halomethanes of the general formula R₄₋ₙCXₙ where R=H, D or combinations thereof, X=Cl, Br, I or combinations thereof, and n=1-4;

(6) silylmethanes of the general formula (R₃Si)ₙCRₙ₄₋ₙ where R=H, D and n=1-4;

(7) halosilylmethanes of the general formula (X_{3-y}R_{y}Si)ₙCR₄₋ₙ where R=H, D or combinations thereof, X=Cl, Br, I or combinations thereof, y=0-3 and n=1-4; and

(8) halosilylhalomethanes of the general formula (X_{3-y}R_{y}Si)ₙCZ₄₋ₙ where R=H, D or combinations thereof, X=Cl, Br, I or combinations thereof, Z=H, D, Br, I, Cl or combinations thereof, y=0-3 and n=1-4.

Selectively grown silicon-carbon alloy films can also be doped with electrically active elements such as boron, phosphorus, arsenic or antimony by combining the appropriate dopant sources to the film growth reaction. The most preferred dopant sources are those for boron doped silicon and N-type-doped silicon as described in Cases 3 and 4 above, respectively.

Case 6: Intrinsic Germanium+Extrinsic Br-Etch Source Reactant

For fabricating Ge-containing films using an independently introduced Br-etch source reactant, the preferred Br-etchant sources are the same as those for the selective epitaxial growth of Si-containing materials, and the following classes of germanium source precursors are preferred:

(9) germanes or germanium hydrides of the general formula GeₙR₂ₙ₊₂ where n 1-3 and R=H, D or combinations thereof;

(10) halogermanes of the general formula X₄₋ₙGeRₙ where n=0-3, R=H, D or combinations thereof, and X=Cl, Br, I or combinations thereof; and

(11) halodigermanes of the general formula X_{y}RₘGe—GeRₙX_{z} where n=m=0, 1 or 2 independent of one another, y=z=1-3 independent of one another, y+m=3, n+z=3, R=H, D or combinations thereof, and X=Cl, Br, I or combinations thereof.

The use of mixtures of the foregoing classes of chemical precursors described in classes (9)-(11) is also suitable for use in the invention.

Case 7: Intrinsic Germanium+In Situ Br-Etchant

For embodiments that do not include the formal introduction of a Br-etchant source as a reactant in the selective epitaxial growth of the Ge-containing film, the Br used to etch the nuclei from the exposed dielectric surfaces is supplied in situ by the decomposition of one or more of the Ge-source precursors. In this case, precursors selected from group (10) where X=Br and n=1-3, and group (11) where X=Br and y z=1 or 2 are preferred.

Mixtures of compounds described in Classes (9)-(11) are also suitable for use in the present invention. Additionally, mixtures of multiple precursors with different chemical stoichiometry from the classes defined by Classes (10) or (11) can be used.

Case 8: Doped Germanium

In another embodiment of the invention, additional dopant sources may be added to the film growth reaction during selective epitaxial growth of Ge-containing materials, either with or without the formal introduction of a Br-etchant source. Ge-containing films doped with electrically-active dopants such as boron or N-type dopants can be selectively grown by using the boron dopant sources described previously in Case 3 or the N-type dopants described previously in Case 4. The preferred Ge-source precursors are the same as those described for the SEG of intrinsic Ge either with or without the formal introduction of a Br-etchant source as described in Cases 6 and 7, respectively.

Case 9: Ge₁₋ₓCₓ Alloy Films

In some embodiments of the invention, selective epitaxial growth of Ge₁₋ₓCₓ alloy films, either with or without the formal introduction of a Br-etchant source, can be achieved through addition of one or more carbon-source precursors to the Ge reactants during growth. In some cases, the carbon source precursor may be a source of additional Ge, as well. The preferred carbon source precursors (to be used in conjunction with the preferred Ge-source precursors described previously) include precursors belonging to the following classes:

(12) halomethanes of the general formula R₄₋ₙCXₙ where R H, D or combinations thereof, X=Cl, Br, I or combinations thereof, and n=1-4;

(13) germylmethanes of the general formula (R₃Ge)ₙCR₄₋ₙ where R=H, D or combinations thereof and n=1-4;

(14) halogermylmethanes of the general formula (X_{3-y}R_{y}Ge)ₙCR₄₋ₙ where R=H, D or combinations thereof, X=Cl, Br, I or combinations thereof, y=0-3, and n=1-4; and

(15) halogermylhalomethanes of the general formula (X_{3-y}R_{y}Ge)ₙCZ₄₋ₙ where R H, D or combinations thereof, X=Cl, Br, I or combinations thereof, Z=H, D, Br, I, Cl or combinations thereof, y=0-3, and n=1-4

Any source of carbon that yields a selectively grown, germanium-carbon alloy film can be utilized without departing from the scope of the invention. The carbon source precursors described in Classes (12)-(15) are preferred.

In addition to the carbon and germanium sources described above, germanium-carbon alloy films can be doped with electrically active elements such as boron, phosphorus, arsenic or antimony by combining the appropriate dopant sources to the film growth reaction. The most preferred dopant sources are those described previously in Cases 3 and 4, but any sources of dopant elements that yield a selectively grown doped germanium-carbon alloy film may be used without departing from the scope of the invention.

Case 10: Si₁₋ₓGeₓ and Si_{1-x-y}GeₓC_{y} Alloy Films

Si-source precursors and Ge-source precursors can be combined to selectively grow intrinsic SiGe alloy films in either the presence or absence of an extrinsic Br-etchant source. The preferred Si-source precursors are those described previously in Cases 1 and 2, and the preferred Ge-source precursors are those described previously in Case 6. More preferably, the mixtures include the Si-source precursors described in Group (2) where n=2 and X=Br or I and the Ge-source precursors described in Group (10) where X=Br and n=2.

In addition to the silicon and germanium sources described above, silicon-germanium alloy films can be selectively grown using the Si-sources and Ge-sources described previously for the SEG of SiGe alloy films, in combination with the use of the carbon sources described previously in Cases 5 and 6 for the SEG of intrinsic Si_{1-y}C_{y} and Ge₁₋ₓCₓ films, respectively. The most preferred sources of carbon are those described previously in Case 5. Both SiGe and SiGeC films can be doped with electrically active elements such as boron, phosphorus, arsenic or antimony by combining the appropriate dopant sources to the film growth reaction. The most preferred dopant sources are those described previously in Cases 3 and 4, but any sources of dopant elements that yield a selectively grown doped germanium-carbon alloy film may be used without departing from the scope of the invention.

Case 11: Ge₁₋ₓSnₓ Alloy Films

In one preferred embodiment related to engineered substrates, Ge-source and Sn-source precursors are used either with or without the formal introduction of Br-etchant source or, more preferably, with HI (g) or I₂ vapor, to selectively grow Ge₁₋ₓSnₓ alloy films on single crystal seed windows exposed within a dielectric layer. The films may be strained, partially strain-relaxed or fully strain-relaxed depending upon their thickness and the chemical identity of the substrate material in the exposed single crystal seed windows. The preferred Ge-source precursors are those in Classes (9)-(11). The preferred precursors in Group (11) include those where X=I and y=z=2. The preferred precursors in Group (10) include those where X=I and n=3. The Sn-source precursors suitable for the invention include without limitation SnX₄ (wherein X=Br or I), R₄₋ₙSnXₙ (where R=H, D, and combinations thereof, n=1-3 and X=Br or I), SnH₄ and SnD₄, particularly dilute mixtures of SnD₄ and H₂. Additionally the films can be doped with electrically active elements by using additional dopant source gases described in Cases 3 and 4.

### General Process Parameters

Substrate temperature less than about 750° C. are preferred for materials containing Si or Ge, preferably within a range of about 550° C. to about 750° C. for Si and within a range of about 500° C. to about 700° C. for materials containing Ge. The processes can be carried out at total pressures from about 1×10⁻⁵ Torr to about 1600 Torr, preferably less than about 760 Torr. Optimal precursor partial pressures will depend strongly on the masking dielectric, the mask pattern and density, the substrate temperature and the total pressure and are best determined empirically, for a given precursor and patterned substrate, using convention methods. Within such parameters, the SEG film should be grown at or near the highest possible growth rate while maintaining acceptable selectivity to the exposed dielectric surfaces, acceptable crystal quality, and achieving the highest possible thickness and elemental concentration uniformities across the substrate surface (in the seed windows). Preferably, the range of partial pressures considered for the precursors of the present invention falls within a range of about 1×10⁻⁶ to about 100 volume percent, based upon total gas volume, with the remainder (if any) comprised of the Br-etchant source or carrier gas.

There are several processing modes for generating SEG of Si-containing and Ge-containing films using a Br-etchant source in conjunction with additional source precursors. These include without limitation: (a) processes in which both the Si or Ge source precursors and the Br-etchant source are continuously flowed into the reactor chamber containing the patterned substrates; (b) processes in which a ‘pulse’ of a Br-etchant source is periodically introduced into the reactor chamber along with a continuous flow of the Si or Ge source precursors; (c) processes in which a ‘pulse’ of Si or Ge source precursors is periodically introduced into the reactor chamber along with a continuous flow of a Br-etchant source; and (d) processes in which the Si or Ge source precursors are introduced separately and independently from the Br-etchant source in a ‘cyclic’ process that involves discrete SEG of Si-containing and Ge-containing thin films and discrete etching reactions. Preferably, the processes use continuous flows of both source precursors and a Br-etchant source.

Similarly, there are several processing modes for generating SEG of Si-containing and Ge-containing films in which no Br-etchant source is formally introduced to the source precursors. These include without limitation: (a) the use a continuous flow of one or more source precursors, where the ratio of the partial pressures is kept constant throughout the selective film growth; (b) the use of a continuous flow of one or more source precursors where the ratio of the partial pressures is not kept constant throughout the selective film growth; and (c) the use of ‘cyclic’ processes in which the flow of one or more of the source precursors is discontinuous. In embodiments having mixtures of more than one source precursor, preferably at least one of them contains Br.

The selective growth of the Si-containing and Ge-containing films according to the invention may involve complex structures that contain multiple films sequentially grown on one another, and that these films may have different chemical composition which varies continuously or discontinuously with respect to the initial seed window surfaces. In these types of processes, the partial pressure ratios for each of the component films should be separately optimized for each of the reactant gas mixtures to be used in their growth.

### EXAMPLES

In the all of the examples described below, the patterned substrate was prepared for low temperature epitaxial film growth with the desired pattern size, density and sidewall orientation (with respect to the single crystal seed windows), and the single crystal seed windows and dielectric surfaces were properly cleaned using a combination of wet chemical or dry cleaning step, using known methods. The substrates were also subject to a wet etch comprising the use of HF-acid or buffered HF-acid, after which they were loaded into a reactor chamber or a load-lock chamber connected to a reactor chamber as quickly as possible. Depending upon the intended application of the films that are to be selectively grown on the patterned substrates, an additional cleaning step (e.g. ‘pre-bake’ or other in-situ clean) may be performed in the reactor chamber prior to film growth.

It is further noted that Br₂ is highly reactive with silicon and germanium hydride compounds and that, in some cases where it is used as the Br-etchant source, it may be preferable to introduce the Br₂ into the reactor chamber without first mixing it with the other source precursors. Likewise, the use of diluted mixtures of Br₂ is considered to be preferred when one or more of the source precursors is a silane or germane.

### Example 1

A patterned substrate is loaded into a reactor chamber, the temperature is allowed to equilibrate at 650° C. and the total pressure is allowed to equilibrate at 10 Torr under a flow of 40 standard liter per minute (SLM) of ultra-high purity hydrogen. A flow of 20 standard cubic centimeter per minute (sccm) of silane (SiH₄) is then introduced to the reactor chamber in combination with a flow of 0.5 sccm of Br₂ vapor to selectively grow an intrinsic silicon film on the exposed single crystal seed window surfaces, wherein the thickness of said film is less than or equal to that of the patterned dielectric film thickness.

Alternatively, the temperature is lowered to 630° C., GeH₄ is added to the reactants, and the selectively grown film is intrinsic SiGe.

### Example 2

A patterned substrate is loaded into a reactor chamber, the temperature is allowed to equilibrate at 550° C. and the total pressure is allowed to equilibrate at 5 Torr under a flow of 60 standard liter per minute (SLM) of ultra-high purity hydrogen. A flow of 10 standard cubic centimeter per minute (sccm) of disilane (Si₂H₆) is then introduced to the reactor chamber in combination with a flow of 2 sccm of Br₂/H₂ mixture (10% Br₂) that is not pre-mixed with the disilane, to selectively grow an intrinsic silicon film on the exposed single crystal seed window surfaces, wherein the thickness of said film is less than or equal to that of the patterned dielectric film thickness.

Alternatively, a flow of 70 sccm of phosphine (300 ppm PH₃ in ultra-high purity H₂) is added to the mixture and the flow rate of the Br H₂ mixture is increased to 7 sccm to selectively grow a phosphorus-doped silicon film.

### Example 3

A patterned substrate is loaded into a reactor chamber, the temperature is allowed to equilibrate at 600° C. and the total pressure is allowed to equilibrate at 30 Torr under a flow of 20 standard liter per minute (SLM) of ultra-high purity hydrogen. A flow of 10 standard cubic centimeter per minute (sccm) of diiodosilane (I₂SiH₂) is then introduced to the reactor chamber in combination with a flow of 5 sccm of HBr gas to selectively grow an intrinsic silicon film on the exposed single crystal seed window surfaces, wherein the thickness of said film is less than or equal to that of the patterned dielectric film thickness.

Alternatively, a flow of 100 sccm of diborane (100 ppm B₂H₆ in ultra-high purity H₂) is added to the mixture and the flow rate of the HBr is increased to 10 sccm to selectively grow a boron-doped silicon film.

### Example 4

A patterned substrate is loaded into a reactor chamber, the temperature is allowed to equilibrate at 575° C. and the total pressure is allowed to equilibrate at 760 Torr under a flow of 40 standard liter per minute (SLM) of ultra-high purity hydrogen. A flow of 40 standard cubic centimeter per minute (sccm) of bromosilane (BrSiH₃), delivered from a vessel cooled to −50° C., is then introduced to the reactor chamber in combination with a flow of 1 sccm of HBr/Br₂ mixture (98% HBr, 2% Br₂) to selectively grow an intrinsic silicon film on the exposed single crystal seed window surfaces, wherein the thickness of said film is less than or equal to that of the patterned dielectric film thickness.

### Example 5

A patterned substrate is loaded into a reactor chamber, the temperature is allowed to equilibrate at 610° C. and the total pressure is allowed to equilibrate at 80 Torr under a flow of 80 standard liter per minute (SLM) of ultra-high purity hydrogen. A flow of 15 standard cubic centimeter per minute (sccm) of 1,2-diiododisilane (IH₂SiSiH₂I) is then introduced to the reactor chamber in combination with a flow of 5 sccm of HBr diluted in H₂/N₂ (50% HBr, 47% H₂ and 3% N₂) to selectively grow an intrinsic silicon film on the exposed single crystal seed window surfaces, wherein the thickness of said film is less than or equal to that of the patterned dielectric film thickness.

Alternatively, the temperature is lowered to 550° C., GeH₄ is added to the reactants, and the selectively grown film is intrinsic SiGe.

### Example 6

A patterned substrate is loaded into a reactor chamber, the temperature is allowed to equilibrate at 525° C. and the total pressure is allowed to equilibrate at 1 Torr under a flow of 20 standard liter per minute (SLM) of ultra-high purity hydrogen. A flow of 10 standard cubic centimeter per minute (sccm) of 1,3-dibromotrisilane (BrH₂SiSiH₂SiH₂Br) is then introduced to the reactor chamber in combination with a flow of 1 sccm of Br₂ vapor to selectively grow an intrinsic silicon film on the exposed single crystal seed window surfaces, wherein the thickness of said film is less than or equal to that of the patterned dielectric film thickness.

### Example 7

A patterned substrate is loaded into a reactor chamber, the temperature is allowed to equilibrate at 650° C. and the total pressure is allowed to equilibrate at 30 Torr under a flow of 40 standard liter per minute (SLM) of ultra-high purity hydrogen. A flow of 15 standard cubic centimeter per minute (sccm) of silane (SiH₄) combined with a flow of 5 sccm of dibromosilane (Br₂SiH₂) is then introduced to the reactor chamber in combination with a flow of 3 sccm of HBr gas to selectively grow an intrinsic silicon film on the exposed single crystal seed window surfaces, wherein the thickness of said film is less than or equal to that of the patterned dielectric film thickness.

Alternatively, a flow of 50 sccm of diborane (200 ppm B₂H₆ in ultra-high purity H₂) is added to the mixture and the flow rate of the HBr is increased to 5 sccm to selectively grow a boron-doped silicon film.

### Example 8

A patterned substrate is loaded into a reactor chamber, the temperature is allowed to equilibrate at 550° C. and the total pressure is allowed to equilibrate at 5 Torr under a flow of 20 standard liter per minute (SLM) of ultra-high purity hydrogen. A flow of 4 standard cubic centimeter per minute (sccm) of disilane (Si₂H₆) combined with a flow of 10 sccm of tribromosilane (Br₃SiH) is then introduced to the reactor chamber in combination with a flow of 1 sccm of Br₂ vapor (10% diluted in He) to selectively grow an intrinsic silicon film on the exposed single crystal seed window surfaces, wherein the thickness of said film is less than or equal to that of the patterned dielectric film thickness.

Alternatively, a flow of 90 sccm of phosphine (100 ppm PH₃ in ultra-high purity H₂) is added to the mixture and the flow rate of the Br He mixture is increased to 3 sccm to selectively grow a phosphorus-doped silicon film.

### Example 9

A patterned substrate is loaded into a reactor chamber, the temperature is allowed to equilibrate at 630° C. and the total pressure is allowed to equilibrate at 15 Torr under a flow of 30 standard liter per minute (SLM) of ultra-high purity hydrogen. A flow of 20 standard cubic centimeter per minute (sccm) of silane (SiH₄) combined with a flow of 15 sccm of diidosilane (I₂SiH₂) is then introduced to the reactor chamber in combination with a flow of 8 sccm of a HBr/Br₂ (60% HBr, 5% Br₂, 35% H₂) mixture to selectively grow an intrinsic silicon film on the exposed single crystal seed window surfaces, wherein the thickness of said film is less than or equal to that of the patterned dielectric film thickness.

Alternatively, the temperature is lowered to 600° C. and GeH₄ is substituted for SiH₄ and the selectively grown film is intrinsic SiGe (where no stoichiometry is implied).

### Example 10

A patterned substrate is loaded into a reactor chamber, the temperature is allowed to equilibrate at 580° C. and the total pressure is allowed to equilibrate at 20 Torr under a flow of 35 standard liter per minute (SLM) of ultra-high purity hydrogen. A flow of 10 standard cubic centimeter per minute (sccm) of iodosilane (ISiH₃), delivered from a vessel cooled to −20° C., combined with a flow of 5 sccm of dibromosilane (Br₂SiH₂) is then introduced to the reactor chamber in combination with a flow of 2 sccm of HBr gas to selectively grow an intrinsic silicon film on the exposed single crystal seed window surfaces, wherein the thickness of said film is less than or equal to that of the patterned dielectric film thickness.

Alternatively, a flow of 1 sccm of dibromomethane (Br₂CH₂) is added to the mixture to selectively grow a silicon-carbon alloy film.

### Example 11

### HBT Structures

In this embodiment, a stacked structure consisting of three or more regions is used to make the epitaxial base layer of a HBT. The general form of the stacked structure is Si/SiGe (Ge-concentration ramped ‘up’)/SiGe (peak Ge-concentration; constant)/SiGe (Ge-concentration ramped ‘down’) doped with boron (B) or SiGeC doped with B/SiGe (Ge-concentration ramped ‘down’ to approximately zero)/Si, wherein no stoichiometry is implied. The thickness and elemental concentrations of each of these layers is dependent upon the device design and may vary considerably within a given design geometry (i.e. 45-nm gate length or 65-nm gate length). The intrinsic SiGe regions are generally comprised of layers that have a graded Ge-concentration both prior to and after a SiGe region that has the highest and constant Ge-concentration. Usually, the graded portion of the SiGe layer closest to the substrate has its Ge concentration ramped up to the peak Ge-concentration with a steep slope, while the SiGe layer after the peak Ge-concentration layer has its Ge-concentration ramped down with a more gradual slope. The boron-doped SiGe or SiGeC layer is generally placed within the ramped ‘down’ portion of the SiGe layer and is generally very narrow (150 Å or less). It is highly preferred that the substrate temperature be as low as possible during the growth of the base layer to enable the selective growth of strained SiGe/SiGeC layers, to improve the substitutionality of the carbon within the SiGeC layer and to minimize diffusion of the boron. A specific example follows.

A patterned substrate is loaded into a reactor chamber after receiving various wet cleaning steps known to those skilled in the art. The temperature of the substrate is equilibrated at 850° C. for 5 minutes under a flow of 80 SLM of ultra-high purity hydrogen (‘pre-bake’) at atmospheric pressure. The substrate is then allowed to cool to 600° C. under a flow of 40 SLM of ultra-high purity hydrogen and the pressure within the reactor is lowered to 10 Torr. A mixture of disilane (3 sccm, 10% Si₂H₆/90% ultra-high purity H₂), tribromosilane (20 sccm, delivered from a bubbler using ultra-high purity hydrogen carrier gas) and AsH₃ (20 sccm, 100 ppm AsH₃ in ultra-high purity hydrogen) is then introduced into the reactor chamber to selectively grow a silicon film doped with 5×10¹⁶ As atoms/cm³ that has a thickness of 100 Å. Next, a mixture of germane (2% in ultra-high purity hydrogen) and tribormosilane (20 sccm, delivered from a bubbler using ultra-high purity H₂ carrier gas) is used to selectively grow a steeply Ge-concentration graded SiGe layer that is 75 Å thick by varying the flow of the germane from 0 sccm to 50 sccm over 10 seconds. Then, a constant Ge-concentration layer that is 150 Å thick is selectively grown by continuing the flows of germane and tribromosilane for an additional 15 seconds. Next, the flow of the germane is ramped down from 50 sccm to 30 sccm over 10 seconds to selectively grow an intrinsic SiGe layer with continuously, smoothly decreasing Ge-concentration that is 75 Å thick, while continuing the flow of tribromosilane. A flow of 2 sccm of H₃CI is then introduced, along with a flow of 100 sccm of B₂H₆ (100 ppm in ultra-high purity hydrogen) for 10 seconds to selectively grow a SiGeC(B) layer that is 100 Å thick, while the germane flow rate is continuously ramped down from 30 sccm to 10 sccm and the tribromosilane flow is continued. The flows of H₃CI and B₂H₆ are then abruptly terminated, while the germane flow is continuously ramped down from 10 sccm to 0 sccm to selectively grow an intrinsic SiGe film that is 100 Å thick. Finally, the flow of the germane is terminated, the flow of tribromosilane is terminated and disilane (as before) is introduced at a flow of 5 sccm in combination with a flow of 4 sccm of HBr to selectively grow an intrinsic silicon ‘cap’ layer that is 150 Å thick. This completes the selective epitaxial growth of the base layer film structure. It is appreciated by those skilled in the art that many possible embodiments of the invention are possible and that the example is meant to illustrate one possible embodiment, without limiting the invention.

The embodiments and examples set forth herein were presented in order to best explain the present invention and its practical application and to thereby enable those of ordinary skill in the art to make and use the invention. However, those of ordinary skill in the art will recognize that the foregoing description and examples have been presented for the purposes of illustration and example only. The description as set forth is not intended to be exhaustive or to limit the invention to the precise form disclosed. Many modifications and variations are possible in light of the teachings above without departing from the spirit and scope of the forthcoming claims. For example, the temperatures, total pressures, and partial pressures may vary depending upon the precursor or etchant materials, or the types of flow conditions or carrier gas used, in order to optimize the properties of films selectively deposited according to the invention.

What is claimed is:

1. A low temperature process for selective growth of an epitaxial layer on a patterned substrate comprising:
(a) introducing at least one patterned substrate into a deposition chamber;
(b) providing a substrate temperature within the chamber;
(c) providing a total pressure within the chamber; and
(d) introducing at least one source precursor and at least one compound into the deposition chamber, wherein the at least one compound comprises at least one element selected from the group consisting of Br and I; and
(e) maintaining the substrate temperature at less than about 750° C. for a period of time sufficient to selectively grow an epitaxial layer on the substrate.

2. The process of claim 1, further comprising heating the at least one compound prior to introducing the at least one compound into the chamber.

3. The process of claim 1, wherein the at least one compound is selected from the group consisting of Br₂ and HBr.

4. The process of claim 1, further comprising mixing the at least one compound with a carrier gas prior to introducing the compound into the chamber.

5. The process of claim 1, wherein chemical vapor deposition is used to selectively grow the epitaxial layer.

6. The process of claim 1, wherein the at least one source precursor comprises at least one of Si, Ge, C, and Sn.

7. The process of claim 6, wherein the at least one source precursor is selected from the group consisting of silanes, halosilanes, halodisilanes, halotrisilanes, halomethanes, silylmethanes, halosilylmethanes, halosilylhalomethanes and combinations thereof.

8. The process of claim 6 wherein the at least one source precursor is selected from the group consisting of germanes, halogermanes, halodigermanes, halomethanes, germylmethanes, halogermylmethanes, halogermylhalomethanes and combinations thereof.

9. The process of claim 1, wherein the at least one compound is a bromine etchant source.

10. The process of claim 1, wherein the at least one compound is a source precursor.

11. The process of claim 1, wherein at least two compounds are introduced into the chamber.

12. The process of claim 11, wherein at least one of the at least two compounds is a bromine etchant source and at least one of the at least two compounds is a source precursor.

13. The process of claim 1, wherein at least two source precursors are introduced into the chamber.

14. The process of claim 13, wherein at least one of the at least two precursors comprises bromine.

15. The process of claim 13, wherein the at least one of the at least two precursors is a Br etchant source.

16. The process of claim 13, wherein at least one of the at least two precursors comprises Ge and at least one of the at least two precursors comprises Si.

17. The process of claim 1, wherein the at least one precursor comprises Si and the substrate temperature is less than about 750° C.

18. The process of claim 1, wherein the at least one precursor comprises Ge and the substrate temperature is less than about 700° C.

19. The process of claim 1, wherein the at least one precursor comprises Sn and the substrate temperature is less than about 650° C.

20. The process of claim 13, wherein at least one of the at least two precursors comprises Sn, at least one of the at least two precursors comprises Ge, and the substrate temperature is less than about 500° C.

21. The process of claim 1, wherein the substrate temperature is from about 400° C. to about 750° C., or any temperature range therein.

22. The process of claim 1, wherein the total pressure is less than about 800 Torr.

23. The process of claim 1, wherein at least one of the at least one compound, and at least one of the at least one source precursor, is selected from the group consisting of:

| | |
|---|---|
| Br₄₋ₓSiHₓ | (x = 0–3); |
| (BrₓH₃₋ₓSi)₂ | (x = 1–2); |
| Br₄₋ₓGeHₓ | (x = 0–3); |
| (BrₓH₃₋ₓGe)₂ | (x = 1–2); |
| I₄₋ₓSiHₓ | (x = 0–3); |
| (IₓH₃₋ₓSi)₂ | (x = 1–2); |
| I₄₋ₓGeHₓ | (x = 0–3); |
| (IₓH₃₋ₓGe)₂ | (x = 1–2); and |
| SnD₄. | |

24. An epitaxial layer fabricated according to the process of claim 1.

25. The epitaxial layer of claim 24, wherein the layer comprises at least one of Si, Ge, Sn, C, Br and I.

26. A structure comprising the layer of claim 25.

27. The structure of claim 26, wherein the structure is at least one of a MOSFET device, an emitter structure, an elevated source-drain structure, a heterojunction bipolar transistor structure, an epitaxial lateral overgrowth structure, a DRAM structure, an engineered substrate structure, and a component thereof.

28. A process for cleaning residue from at least one surface inside a deposition chamber, the process comprising:
(a) introducing at least one etchant source comprising bromine into the chamber;
(b) providing a temperature within the chamber;
(c) providing a total pressure within the chamber; and
(d) flowing the at least one etchant source for a period of time sufficient to remove a substantial portion of the residue.

29. The process of claim 28, further comprising heating the at least one etchant source prior to introducing the source into the chamber

30. The process of claim 28, further comprising mixing the at least one etchant source with a carrier gas prior to introducing the source into the chamber.

31. The process of claim 28, wherein the at least one etchant source is selected from the group consisting of Br₂ and HBr.

32. The process of claim 28, wherein the temperature is greater than about 550° C.

33. The process of claim 28, wherein the total pressure is less than about 800 Torr.

34. A surface cleaned according to the process of claim 28, wherein the surface is provided by at least one of a patterned substrate, an inner surface of the chamber, a chamber component, an object having no physical or functional connection with the chamber, and combinations thereof.

35. A composition for selective epitaxial growth, wherein the composition comprises at least one source precursor and at least one compound, wherein the at least one compound comprises at least one element selected from the group consisting of Br and I.

36. The composition of claim 35, wherein the at least one source precursor comprises at least one of Si, Ge, C, and Sn.

37. The composition of claim 36, wherein the at least one source precursor is selected from the group consisting of silanes, halosilanes, halodisilanes, halotrisilanes, halomethanes, silylmethanes, halosilylmethanes, halosilylhalomethanes and combinations thereof.

38. The composition of claim 36 wherein the at least one source precursor is selected from the group consisting of germanes, halogermanes, halodigermanes, halomethanes, germylmethanes, halogermylmethanes, halogermylhalomethanes and combinations thereof.

39. The composition of claim 35, wherein at least one compound is a bromine etchant source.

40. The composition of claim 35, wherein the at least one compound is a source precursor.

41. The composition of claim 35, wherein the composition comprises at least two compounds.

42. The composition of claim 41, wherein at least one of the at least two compounds is a bromine etchant source and at least one of the at least two compounds is a source precursor.

43. The composition of claim 35, wherein the composition comprises at least two source precursors.

44. The composition of claim 43, wherein at least one of the at least two precursors comprises bromine.

45. The composition of claim 43, wherein the at least one of the at least two precursors is a Br etchant source.

46. The composition of claim 43, wherein at least one of the at least two precursors comprises Ge and at least one of the at least two precursors comprises Si.
